(19) United States
(12) Patent Application Publication
(10) Pub. No.: US 2025/0240882 A1
(43) Pub. Date: Jul. 24, 2025

(54) WIRING CIRCUIT BOARD

(71) Applicant: NITTO DENKO CORPORATION, Osaka (JP)

(72) Inventors: Ikuya HASHIMOTO, Osaka (JP); Takashi YAMAMOTO, Osaka (JP); Ryosuke SASAOKA, Osaka (JP)

(73) Assignee: NITTO DENKO CORPORATION, Osaka (JP)

(21) Appl. No.: 19/025,174

(22) Filed: Jan. 16, 2025

(30) Foreign Application Priority Data
Jan. 22, 2024 (JP) 2024-007690

(51) Int. Cl. H05K 1/02

(52) U.S. Cl. CPC H05K 1/0296; H05K 2201/09027; H05K 2201/09063

(57) ABSTRACT

A wiring circuit board includes a plurality of wiring portions, and a first support portion supporting one end portion of each of the wiring portions. Each of the wiring portions has a metal supporting layer, a first insulating layer, and a wire. The metal supporting layer of each of the wiring portions has a first end portion connected to a first support portion, a body portion, and a first tapered portion widens as it goes from the body portion toward the first end portion.

### CROSS-REFERENCE TO RELATED APPLICATION

The present application claims priority from Japanese Patent Application No. 2024-7690 filed on Jan. 22, 2024, the content of which is hereby incorporated by reference into this application.

### TECHNICAL FIELD

The present invention relates to a wiring circuit board.

### BACKGROUND ART

Conventionally, there has been a known wiring circuit board including a plurality of wiring portions spaced from each other at intervals, and a connecting portion that connects the plurality of wiring portions (for example, see Patent document 1 below).

In the wiring circuit board, the thickness of the wiring portion is larger than (more than twice) the width of the wiring portion. Therefore, the wiring portion can easily be moved in the width direction as compared with in the thickness direction.

### Citation List

### Patent Document

Patent Document 1: Japanese Unexamined Patent Publication No. 2019-212656

### SUMMARY OF THE INVENTION

### Problem to be Solved by the Invention

In the wiring circuit board as described in Patent Document 1, when the wiring portion is moved, there is a possibility that stress is concentrated in the vicinity of the end portion (that is a portion connected to the connecting portion) of the wiring portion. Therefore, there is a possibility that a crack occurs in the wire in the vicinity of the end portion of the wiring portion.

The present invention provides a wiring circuit board capable of suppressing the occurrence of a crack in the wire in the vicinity of the end portion of the wiring portion.

### Means for Solving the Problem

The present invention [1] includes a wiring circuit board including: a plurality of wiring portions extending in a first direction and spaced from each other at an interval; and a first support portion supporting one end portion of each of the plurality of wiring portions in the first direction, wherein each of the plurality of the wiring portions includes: a metal supporting layer; an insulating layer disposed on the metal supporting layer; and a wire disposed on the insulating layer and extending in the first direction, wherein the metal supporting layer of the wiring portion includes: a first end portion connected to the first support portion; a body portion disposed away from the first end portion; and a first tapered portion disposed between the first end portion and the body portion, and wherein a width of the first tapered portion increases as the first tapered portion goes from the body portion toward the first end portion.

According to such a configuration, in the vicinity of the first end portion connected to the first support portion, the metal supporting layer of the wiring portion has a first tapered portion widening as it approaches the first end portion.

Therefore, it is possible to increase the stiffness in the vicinity of one end portion of the wiring portion using the first tapered portion.

In this manner, when the wiring portion is moved, it is possible to suppress the stress in the vicinity of one end portion of the wiring portion being concentrated on the wire. In other words, it is possible to relax the stress on the wire disposed in the vicinity of one end portion of the wiring portion.

As a result, it is possible to suppress the occurrence of a crack in the wire in the vicinity of one end portion of the wiring portion.

The present invention [2] includes the wiring circuit board described in the above-described [1], wherein in the first direction, a length of the first tapered portion is 30% or less of a total length of the wiring portion.

According to such a configuration, it is possible to suppress the decrease in the flexibility of the wiring portion.

The present invention [3] includes the wiring circuit board described in the above-described [1] or [2], wherein the first end portion in the first direction has a length of 200 μm or less.

The present invention [4] includes the wiring circuit board described in any one of the above-described [1] to [3], wherein the first tapered portion has a taper ratio of 0.0010 or more.

According to such a configuration, it is possible to increase the stiffness in the vicinity of one end portion of the wiring portion.

The present invention [5] includes the wiring circuit board described in any one of the above-described [1] to [4], wherein an edge of the first tapered portion in the width direction includes a curve.

The present invention [6] includes the wiring circuit board described in any one of the above-described [1] to [4], wherein an edge of the first tapered portion in the width direction is a straight line.

The present invention [7] includes the wiring circuit board described in any one of the above-described [1] to [6], further including: a second support portion supporting the other end portion of each of the plurality of the wiring portions in the first direction, wherein the metal supporting layer of the wiring portion further includes: a second end portion disposed away from the body portion and connected to the second support portion; and a second tapered portion disposed between the second end portion and the body portion, and wherein a width of the second tapered portion increases as the second tapered portion goes from the body portion toward the second end portion.

According to such a configuration, in the vicinity of the second end portion connected to the second support portion, the metal supporting layer of the wiring portion has a second tapered portion widening as it approaches the second end portion.

Therefore, it is possible to increase the stiffness in the vicinity of the other end portion of the wiring portion by using the second tapered portion.

In this manner, when the wiring portion is moved, it is possible to suppress the stress in the vicinity of the other end portion of the wiring portion being concentrated on the wire. In other words, it is possible to relax the stress on the wire disposed in the vicinity of the other end portion of the wiring portion.

As a result, it is possible to suppress the occurrence of a crack in the wire in the vicinity of the other end portion of the wiring portion.

The present invention [8] includes the wiring circuit board described in the above-described [7], wherein in the first direction, a length of the second tapered portion is 30% or less of a total length of the wiring portion.

According to such a configuration, it is possible to suppress the decrease in flexibility of the wiring portion.

The present invention [9] includes the wiring circuit board described in the above-described [7] or [8], wherein the second end portion in the first direction has a length of 200 μm or less.

The present invention [10] includes the wiring circuit board described in any one of the above-described [7] to [9], wherein the second tapered portion has a taper ratio of 0.0010 or more.

According to such a configuration, it is possible to increase the stiffness in the vicinity of the other end portion of the wiring portion.

The present invention [11] includes the wiring circuit board described in any one of the above-described [7] to [10], wherein an edge of the second tapered portion in the width direction includes a curve.

The present invention [12] includes the wiring circuit board described in any one of the above-described [7] to [10], wherein an edge of the second tapered portion in the width direction is a straight line.

The present invention [13] includes the wiring circuit board described in any one of the above-described [1] to [12], wherein each of the plurality of wiring portions has a plurality of wires.

According to such a configuration, in all the wires provided in the wiring portion, it is possible to suppress the occurrence of a crack.

### Effects of the Invention

According to the wiring circuit board of the present invention, it is possible to suppress the occurrence of a crack in the wire in the vicinity of the end portions of the wiring portion.

### BRIEF DESCRIPTION OF THE DRAWINGS

FIG. 1 shows a plan view of a wiring circuit board as one embodiment of the present invention.

FIG. 2 is a cross-sectional view of the wiring circuit board shown in FIG. 1, taken along line A-A.

FIG. 3 is a cross-sectional view of the wiring circuit board shown in FIG. 1, taken along line B-B.

FIG. 4 is a backside view of the wiring circuit board shown in FIG. 1.

FIG. 5 is an enlarged view of the first end portion shown in FIG. 4.

FIG. 6 is an explanatory view for explaining a modified example (1).

FIGS. 7A and 7B are explanatory views for explaining a modified example (2). FIG. 7A shows a case where the edge of the first tapered portion is exponentially curved outward in the width direction as it approaches the first end portion. FIG. 7B shows a case where the edge of the first tapered portion parabolically extends outward in the width direction as it approaches the first end portion.

FIG. 8 is an explanatory view for explaining a modified example (3).

FIG. 9 is an explanatory view for explaining a modified example (4).

FIG. 10 is an explanatory view for explaining a modified example (5).

FIG. 11 is an explanatory view for explaining a modified example (6).

FIG. 12 is an explanatory view for explaining a modified example (7).

### DESCRIPTION OF THE EMBODIMENT

### 1. Wiring Circuit Board

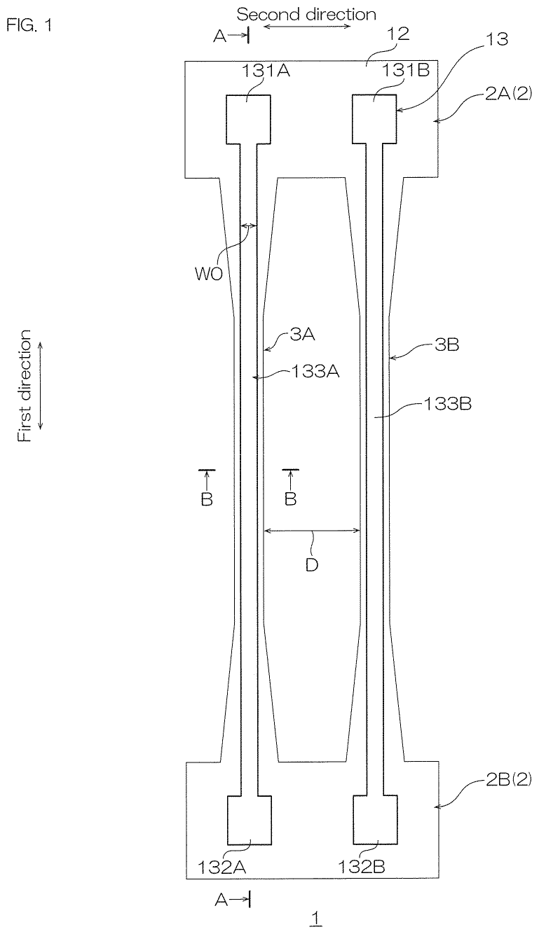

As shown in FIG. 1, the wiring circuit board 1 includes a plurality of support portions 2 (a first support portion 2A and a second support portion 2B), and a plurality of wiring portions 3A and 3B.

The first support portion 2A and the second support portion 2B are spaced from each other at an interval in a first direction. The first direction is a direction in which a wire 133A to be described later extends. The first direction is perpendicular to a thickness direction of the wiring circuit board 1. Each of the first support portion 2A and the second support portion 2B extends in a second direction. The second direction is perpendicular to the thickness direction and intersects the first direction. In the present embodiment, the second direction is perpendicular to both the thickness direction and the first direction. The first support portion 2A supports one end portion of each of the wiring portions 3A and 3B in the first direction. Terminals 131A and 131B of a conductive pattern 13 to be described later are disposed in the first support portion 2A. The second support portion 2B supports the other end portion of each of the wiring portions 3A and 3B in the first direction. The terminals 132A and 132B of the conductive pattern 13 to be described later are disposed in the second support portion 2B.

The wiring portions 3A and 3B are disposed between the first support portion 2A and the second support portion 2B in the first direction. In the present embodiment, each of the wire portions 3A and 3B extends in the first direction. The one end portion of each of the wiring portions 3A and 3B in the first direction is connected to the first support portion 2A. The other end portion of each of the wiring portions 3A and 3B in the first direction is connected to the second support portion 2B. The shape of each of the wiring portions 3A and 3B is not limited. Each of the wiring portions 3A and 3B may have a linear shape or be curved. The wiring portions 3A and 3B are arranged in the second direction. In other words, the wiring portions 3A and 3B are arranged in a direction perpendicular to the direction in which the wiring portion 3A extends. The wiring portions 3A and 3B are spaced from each other at an interval in the second direction. In other words, the wiring portions 3A and 3B are disposed away from each other at an interval in a direction perpendicular to the direction in which the wiring portion 3A extends. At least a portion of the wire 133A of the conductive pattern 13 to be described later is disposed in the wiring portion 3A. At least a portion of a wire 133B of the conductive pattern 13 to be described later is disposed in the wiring portion 3B.

The interval D between the wiring portion 3A and the wiring portion 3B is, for example, 5 μm to 300 μm, preferably 10 μm to 250 μm.

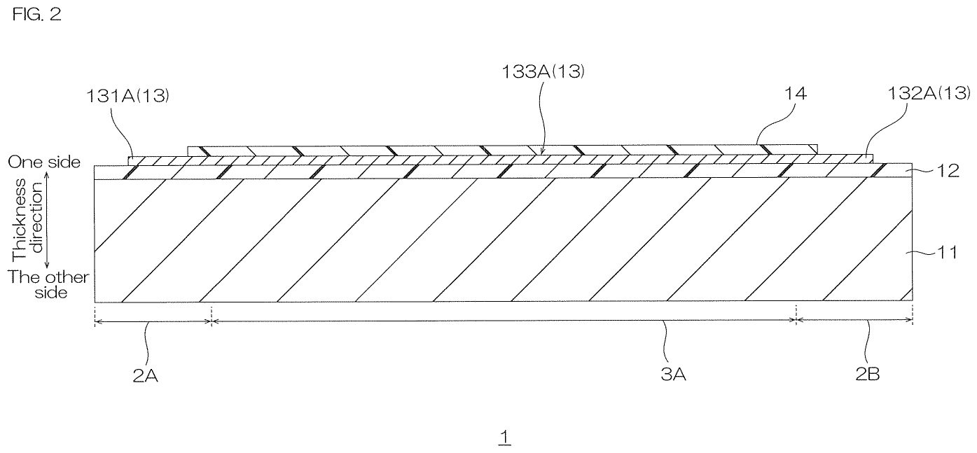

As shown in FIG. 2, the wiring circuit board 1 includes a metal supporting layer 11, a first insulating layer 12 as an example of an insulating layer, a conductive pattern 13, and a second insulating layer 14.

### (1) Metal Supporting Layer

The metal supporting layer 11 is disposed in the support portion 2 (the first support portion 2A and the second support portion 2B) and the wiring portions 3A and 3B. That is, each of the wiring portions 3A and 3B includes a metal supporting layer 11. The metal supporting layer 11 supports the first insulating layer 12, the conductive pattern 13, and the second insulating layer 14. The metal supporting layer 11 is made of metal. Examples of the material of the metal supporting layer 11 include, for example, copper, nickel, cobalt, iron, and the alloys thereof. Examples of the alloy include a copper alloy. As the material of the metal supporting layer 11, preferably, a copper alloy is used.

### (2) First Insulating Layer

The first insulating layer 12 is disposed in the support portion 2 (the first support portion 2A and the second support portion 2B) and in the wiring portions 3A and 3B. That is, each of the wiring portions 3A and 3B has the first insulating layer 12. The first insulating layer 12 is disposed at one side of the metal supporting layer 11 in the thickness direction of the metal supporting layer 11. The first insulating layer 12 is disposed on the metal supporting layer 11. Specifically, the first insulating layer 12 is disposed on one surface of the metal supporting layer 11 in the thickness direction. The first insulating layer 12 is disposed between the metal supporting layer 11 and the conductive pattern 13 in the thickness direction. The first insulating layer 12 insulates the metal supporting layer 11 from the conductive pattern 13. The first insulating layer 12 is made of resin. Examples of the resin include polyimide, maleimide, epoxy resin, polybenzoxazole, and polyester.

### (3) Conductive Pattern

The conductive pattern 13 is disposed at one side of the first insulating layer 12 in the thickness direction. The conductive pattern 13 is disposed on one surface of the first insulating layer 12 in the thickness direction. That is, the wires 133A and 133B are disposed on the first insulating layer 12. The conductive pattern 13 is disposed at the opposite side to the metal supporting layer 11 with respect to the first insulating layer 12 in the thickness direction. The shape of the conductive pattern 13 is not limited.

As shown in FIG. 1, the conductive pattern 13 has a plurality of terminals 131A and 131B, a plurality of terminals 132A and 132B, and a plurality of wires 133A and 133B.

The terminals 131A and 131B are disposed in the first support portion 2A. Each of the terminals 131A and 131B has a square land shape. The terminals 131A and 131B are arranged in the second direction. The terminals 131A and 131B are spaced from each other at an interval in the second direction.

The terminals 132A and 132B are disposed in the second support portion 2B. Each of the terminals 132A and 132B has a square land shape. The terminals 132A and 132B are arranged in the second direction. The terminals 132A and 132B are spaced from each other at an interval in the second direction.

The wire 133A electrically connects the terminal 131A and the terminal 132A. One end portion of the wire 133A is connected to the terminal 131A. The other end portion of the wire 133A is connected to the terminal 132A. At least a portion of the wire 133A is disposed in the wiring portion 3A. That is, the wiring portion 3A has a wire 133A. The wire 133A extends in the first direction.

The wire 133B electrically connects the terminal 131B and the terminal 132B. One end portion of the wire 133B is connected to the terminal 131B. The other end portion of the wire 133B is connected to the terminal 132B. At least a portion of the wire 133B is disposed in the wiring portion 3B. That is, the wiring portion 3B has a wire 133B. The wire 133B extends in the first direction. The wires 133A and 133B are arranged in the second direction. The wires 133A and 133B are spaced from each other at an interval in the second direction.

### (4) Second Insulating Layer

As shown in FIG. 2, the second insulating layer 14 covers all of the wires 133A and 133B. The second insulating layer 14 is disposed on the first insulating layer 12 in the thickness direction. The second insulating layer 14 does not cover the terminals 131A, 131B, 132A, and 132B. The second insulating layer 14 is made of resin. Examples of the resin include polyimide, maleimide, epoxy resin, polybenzoxazole, and polyester.

### 2. Details of Metal Supporting Layer of Wiring Portion

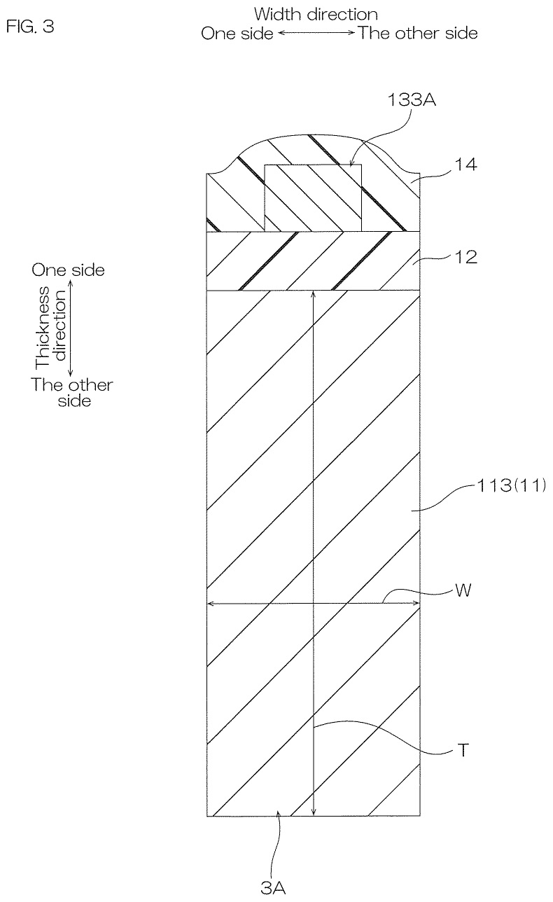

Next, referring to FIGS. 3 to 5, the details of the metal supporting layer 11 of the wiring portion 3A are described. The wiring portion 3B has the same structure as the wiring portion 3A. The description of the metal supporting layer 11 of the wiring portion 3B is omitted.

As shown in FIG. 3, of the metal supporting layer 11 of the wiring portion 3A, a thickness T is larger than a width W.

The “width” is the maximum length in the width direction perpendicular to both the direction in which the wiring portion 3A extends and the thickness direction. In the present embodiment, the width direction is the same direction as the second direction. The width direction may be a direction different from the second direction.

The thickness T of the metal supporting layer 11 is, for example, from 10 μm to 300 μm, preferably from 50 μm to 250 μm.

The metal supporting layer 11 is thicker than the wire 133A (see FIG. 1). The width W of the metal supporting layer 11 is, for example, from 5 μm to 300 μm, preferably from 10 μm to 250 μm.

In the entire of the wiring portion 3A, a ratio (T/W) of the thickness T of the metal supporting layer 11 to the width W of the metal supporting layer 11 is, for example, 2 or more, preferably 3 or more. Hereinafter, the ratio (T/W) is defined as an aspect ratio of the metal supporting layer 11.

When the aspect ratio (T/W) of the metal supporting layer 11 is the lower limit or more, the stiffness of the wiring portion 3A can be ensured in the thickness direction.

The aspect ratio (T/W) of the metal supporting layer 11 is, for example, 30 or less, preferably 10 or less.

The aspect ratio (T/W) of the metal supporting layer 11 may be 2 to 30, or 3 to 10.

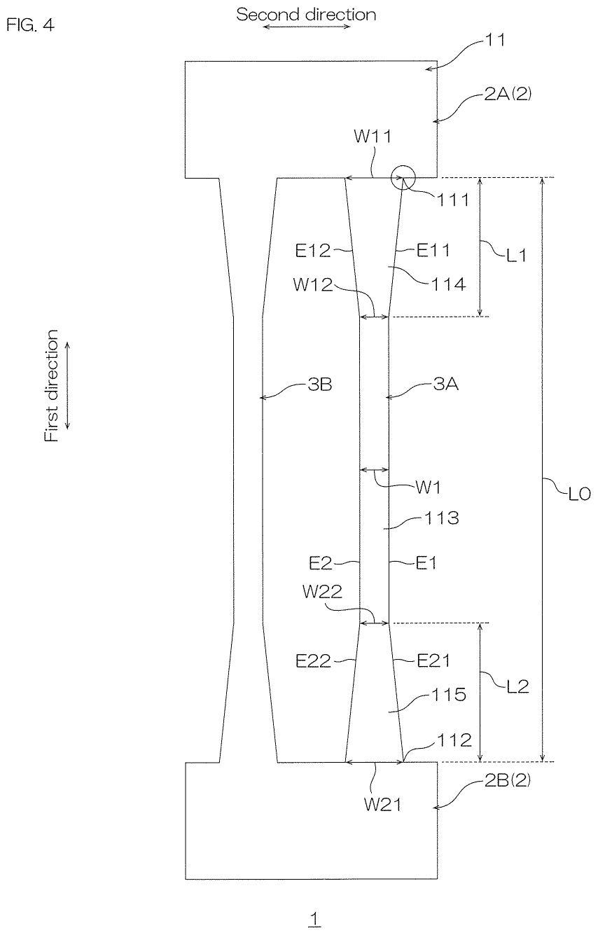

As shown in FIG. 4, the metal supporting layer 11 of the wiring portion 3A has a first end portion 111, a second end portion 112, a body portion 113, a first tapered portion 114, and a second tapered portion 115.

### (1) First End Portion

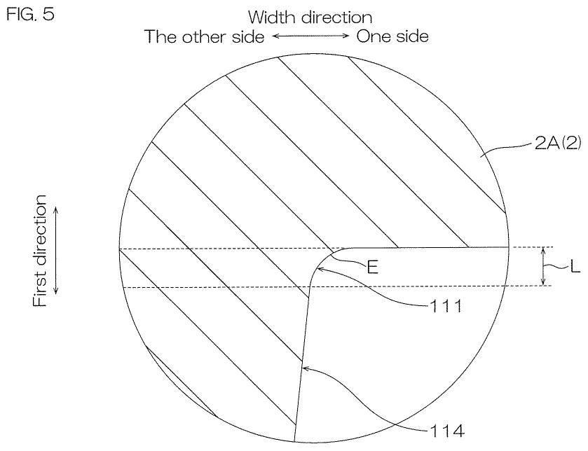

The first end portion 111 is connected to the first support portion 2A. As shown in FIG. 5, the first end portion 111 is disposed between the first support portion 2A and the first tapered portion 114 in the first direction. One edge E of the first end portion 111 in the width direction is curved toward one side in the width direction as it goes from the first tapered portion 114 toward the first support portion 2A. The other edge of the first end portion 111 in the width direction (not shown) is curved toward the other side in the width direction as it goes from the first tapered portion 114 toward the first support portion 2A.

The length L of the first end portion 111 in the first direction is, for example, 200 μm or less, preferably 100 μm or less.

### (2) Second End Portion

As shown in FIG. 4, the second end portion 112 is connected to the second support portion 2B. The second end portion 112 is disposed between the second support portion 2B and the second tapered portion 115 in the first direction. One edge (not shown) of the second end portion 112 in the width direction is curved toward one side in the width direction as it goes from the second tapered portion 115 toward the second support portion 2B. The other edge (not shown) of the second end portion 112 in the width direction is curved toward the other side in the width direction as it goes from the second tapered portion 115 to the second support portion 2B.

The length of the second end portion 112 in the first direction is, for example, 200 μm or less, preferably 100 μm or less.

### (3) Body Portion

The body portion 113 is disposed between the first end portion 111 and the second end portion 112 in the first direction. The body portion 113 is disposed away from the first end portion 111 and the second end portion 112 in the first direction. The body portion 113 extends in the first direction. The body portion 113 does not have a taper. Specifically, one edge E1 of the body portion 113 in the width direction extends substantially parallel to the other edge E2 of the body portion 113 in the width direction.

### (4) First Tapered Portion

The first tapered portion 114 is disposed between the first end portion 111 and the body portion 113 in the first direction. The width of the first tapered portion 114 increases as it goes from the body portion 113 toward the first end portion 111. Specifically, the one end portion of the first tapered portion 114 in the first direction is connected to the first end portion 111 (see FIG. 5). The other end portion of the first tapered portion 114 in the first direction is connected to the body portion 113. A width W11 of the one end portion of the first tapered portion 114 in the first direction is larger than the width W12 of the other end portion of the first tapered portion 114 in the first direction. The width W12 is the same as a width W1 of the body portion 113. One edge E11 of the first tapered portion 114 in the width direction and the other edge E12 of the first tapered portion 114 in the width direction extend in a direction in which they go away from each other as they go from the body portion 113 toward the first end portion 111. Each of the edges E11 and E12 in the width direction of the first tapered portion 114 is a straight line.

In the first direction, a length L1 of the first tapered portion 114 is, for example, 30% or less, preferably 20% or less of a total length L0 of the wiring portion 3A. When the length L1 of the first tapered portion 114 is the upper limit or less, it is possible to suppress the decrease in the flexibility of the wiring portion 3A. The length L1 of the first tapered portion 114 is, for example, 5% or more, preferably 10% or more of the total length L0 of the wiring portion 3A. When the length L1 of the first tapered portion 114 is the lower limit or more, it is possible to increase the stiffness in the vicinity of the one end portion of the wiring portion 3A in the first direction.

The length L1 of the first tapered portion 114 may be 5% to 30% or 10% to 20% of the total length L0 of the wiring portion 3A.

A taper ratio (=(W11-W12)/L1) of the first tapered portion 114 is, for example, 0.0010 or more, preferably 0.0050 or more. When the taper ratio of the first tapered portion 114 is the lower limit or more, it is possible to increase the stiffness in the vicinity of the one end portion of the wiring portion 3A in the first direction. The taper ratio of the first tapered portion 114 is, for example, 0.0300 or less, preferably 0.0200 or less. When the taper ratio of the first tapered portion 114 is the upper limit or less, it is possible to suppress the decrease in the flexibility of the wiring portion 3A.

The taper ratio of the first tapered portion 114 may be 0.0010 to 0.0300, or 0.0050 to 0.0200.

With respect to a width W0 (see FIG. 1) of the wire 133A, a ratio (W11/W0) of the width W11 of the one end portion of the first tapered portion 114 in the first direction is, for example, 20 or less, preferably 15 or less. The ratio (W11/W0) is, for example, 0.1 or more.

### (5) Second Tapered Portion

The second tapered portion 115 is disposed between the second end portion 112 and the body portion 113 in the first direction. The width of the second tapered portion 115 increases as it goes from the body portion 113 toward the second end portion 112. Specifically, the one end portion of the second tapered portion 115 in the first direction is connected to the body portion 113. The other end portion of the second tapered portion 115 in the first direction is connected to the second end portion 112. A width W21 of the other end portion of the second tapered portion 115 in the first direction is larger than a width W22 of the one end portion of the second tapered portion 115 in the first direction. The width W22 is the same as the width W1 of the body portion 113. One edge E21 of the second tapered portion 115 in the width direction and the other edge E22 of the second tapered portion 115 in the width direction extend in a direction in which they go away from each other as they go from the body portion 113 toward the second end portion 112. Each of the edges E21 and E22 in the width direction of the second tapered portion 115 is a straight line.

In the first direction, a length L2 of the second tapered portion 115 is, for example, 30% or less, preferably 20% or less of the total length L0 of the wiring portion 3A. When the length L2 of the second tapered portion 115 is the upper limit or less, it is possible to suppress the decrease in the flexibility of the wiring portion 3A. The length L2 of the second tapered portion 115 is, for example, 5% or more, preferably 10% or more of the total length L0 of the wiring portion 3A. When the length L2 of the second tapered portion 115 is the lower limit or more, it is possible to increase the stiffness in the vicinity of the other end portion of the wiring portion 3A in the first direction.

The length L2 of the second tapered portion 115 may be 5% to 30% or 10% to 20% of the total length L0 of the wiring portion 3A.

A taper ratio (=(W21-W22)/L2) of the second tapered portion 115 is, for example, 0.0010 or more, preferably 0.0050 or more. When the taper ratio of the second tapered portion 115 is the lower limit or more, it is possible to increase the stiffness in the vicinity of the other end portion of the wiring portion 3A in the first direction. The taper ratio of the second tapered portion 115 is, for example, 0.0300 or less, preferably 0.0200 or less. When the taper ratio of the second tapered portion 115 is the upper limit or less, it is possible to suppress the decrease in the flexibility of the wiring portion 3A.

The taper ratio of the second tapered portion 115 may be 0.0010 to 0.0300, or 0.0050 to 0.0200.

With respect to the width W0 (see FIG. 1) of the wire 133A, a ratio (W21/W0) of the width W21 of the other end portion of the second tapered portion 115 in the first direction is, for example, 20 or less, and preferably 15 or less. The ratio (W21/W0) is, for example, 0.1 or more.

### 2. Operations and Effects

(1) According to the wiring circuit board 1, as shown in FIG. 4, the metal supporting layer 11 of the wiring portion 3A has a first tapered portion 114 widening as it approaches the first end portion 111 in the vicinity of the first end portion 111 connected to the first support portion 2A, and a second tapered portion 115 widening as it approaches the second end portion 112 in the vicinity of the second end portion 112 connected to the second support portion 2B.

Therefore, it is possible to increase the stiffness in the vicinity of the one end portion of the wiring portion 3A by using the first tapered portion 114, and it is possible to increase the stiffness in the vicinity of the other end portion of the wiring portion 3A by using the second tapered portion 115.

In this manner, when the wiring portion 3A is moved, it is possible to suppress the stress in the vicinity of the end portions of the wiring portion 3A being concentrated on the wire 133A (see FIG. 1). In other words, it is possible to relax the stress on the wire 133A disposed in the vicinity of the end portions of the wiring portion 3A.

Consequently, it is possible to suppress the occurrence of a crack in the wire 133A in the vicinity of the end portions of the wiring portion 3A.
(2) According to the wiring circuit board 1, as shown in FIG. 4, in the first direction, each of the length L1 of the first tapered portion 114 and the length L2 of the second tapered portion 115 is 30% or less of the total length L0 of the wiring portion 3A.

Therefore, it is possible to suppress the decrease in the flexibility of the wiring portion 3A.
(3) According to the wiring circuit board 1, as shown in FIG. 4, the taper ratio of the first tapered portion 114 is 0.0010 or more.

Therefore, it is possible to increase the stiffness in the vicinity of the one end portion of the wiring portion 3A.

Further, the taper ratio of the second tapered portion 115 is 0.0010 or more.

Therefore, it is possible to increase the stiffness in the vicinity of the other end portion of the wiring portion 3A.

### 3. Modified examples

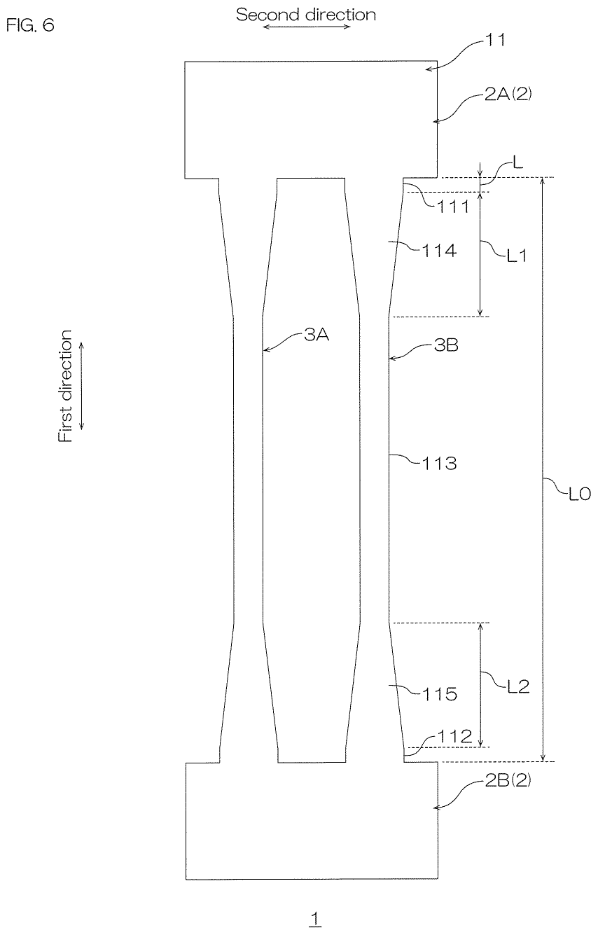

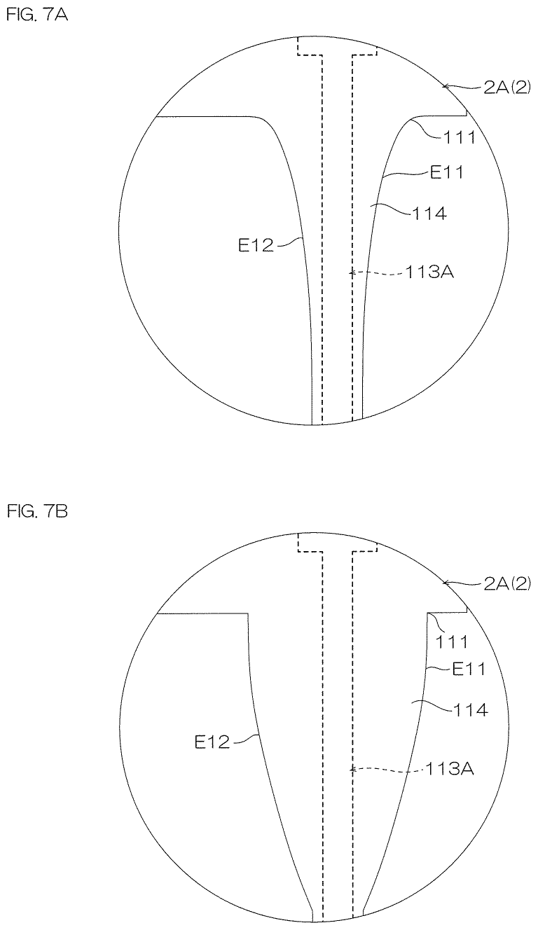

Next, modified examples are described. In the modified examples, the same members as in the above-described embodiment are given the same reference numerals, and the descriptions thereof are omitted.
(1) As shown in FIG. 6, the first end portion 111 may extend straight in the first direction. The length L of the first end portion 111 may exceed 100 μm.
(2) As shown in FIG. 7A and FIG. 7B, the edges E11 and E12 of the first tapered section 114 in the width direction may include a curved line.

For example, as shown in FIG. 7A, the edges E11 and E12 may be exponentially curved outward in the width direction as they approach the first end portion 111.

Further, as shown in FIG. 7B, the edges E11 and E12 may parabolically extend outward in the width direction as they approach the first end portion 111.

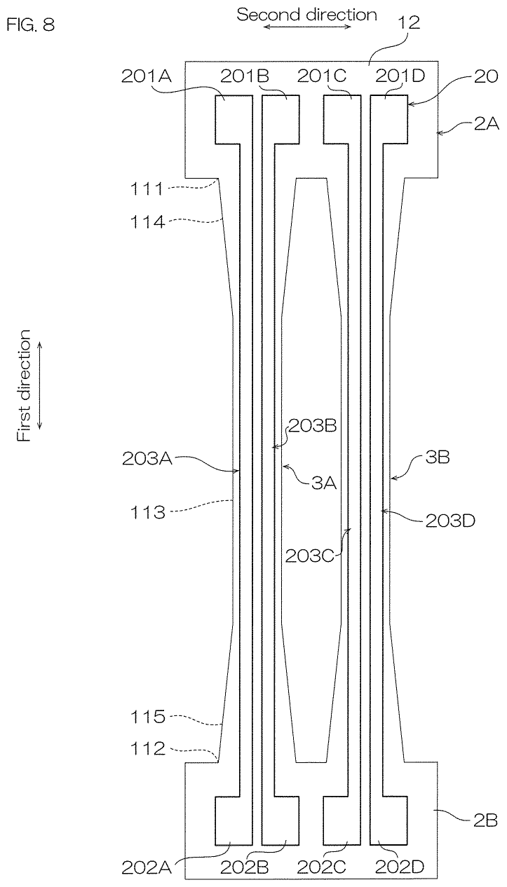

The same applies to the second tapered portion 115 (see FIG. 4). That is, the edges E21 and E22 of the second tapered portion 115 in the width direction may also include a curved line.
(3) As shown in FIG. 8, each of the wiring portions 3A and 3B may have a plurality of wires 203A and 203B. Specifically, the wiring circuit board 1 has a conductive pattern 20 in place of the conductive pattern 13. The conductive pattern 20 has a plurality of terminals 201A, 201B, 201C, and 201D, a plurality of terminals 202A, 202B, 202C, and 202D, and a plurality of wires 203A, 203B, 203C, and 203D.

The terminals 201A, 201B, 201C, and 201D are disposed in the first support portion 2A. The terminals 201A, 201B, 201C, and 201D are arranged in the second direction. The terminals 201A, 201B, 201C, and 201D are spaced apart from each other at intervals in a second direction.

The terminals 202A, 202B, 202C, and 202D are disposed in the second support portion 2B. The terminals 202A, 202B, 202C, and 202D are arranged in the second direction. The terminals 202A, 202B, 202C, and 202D are spaced apart from each other at intervals in the second direction.

The wire 203A electrically connects the terminal 201A and the terminal 202A. The wire 203B electrically connects the terminal 201B and the terminal 202B. The wires 203A and 203B are arranged in the second direction. The wires 203A and 203B are spaced apart from each other at an interval in the second direction. The wire 203A and the wire 203B are disposed in the wiring portion 3A.

The wire 203C electrically connects the terminal 201C and the terminal 202C. The wire 203D electrically connects the terminal 201D and the terminal 202D. The wires 203C and 203D are arranged in the second direction. The wires 203C and 203D are spaced from each other at an interval in the second direction. The wire 203C and the wire 203D are disposed in the wiring portion 3B.

According to this modified example, it is possible to suppress the occurrence of a crack in all the wires 203A, 203B, 203C, and 203D provided in the wiring portion 3A or the wiring portion 3B.
(4) The wiring portion 3A may have a plurality of conductor layers (e.g., a first conductor layer 30A and a second conductor layer 30B).

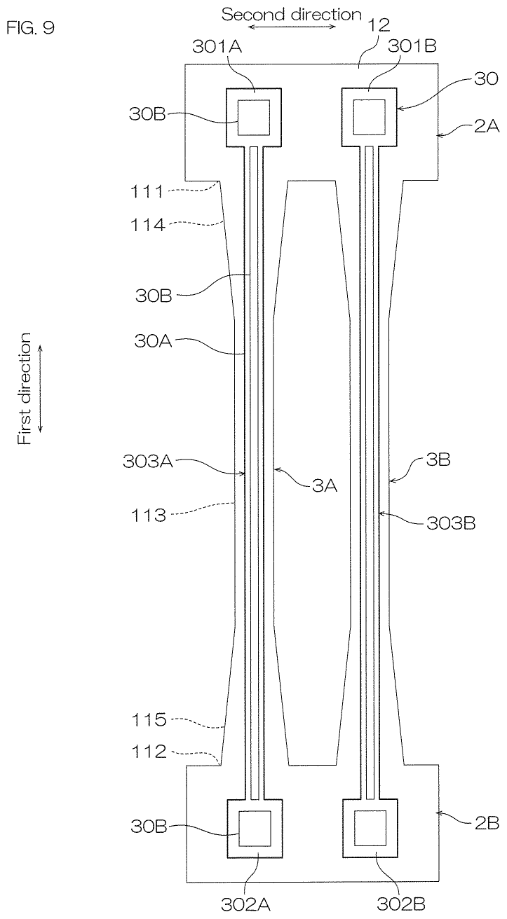

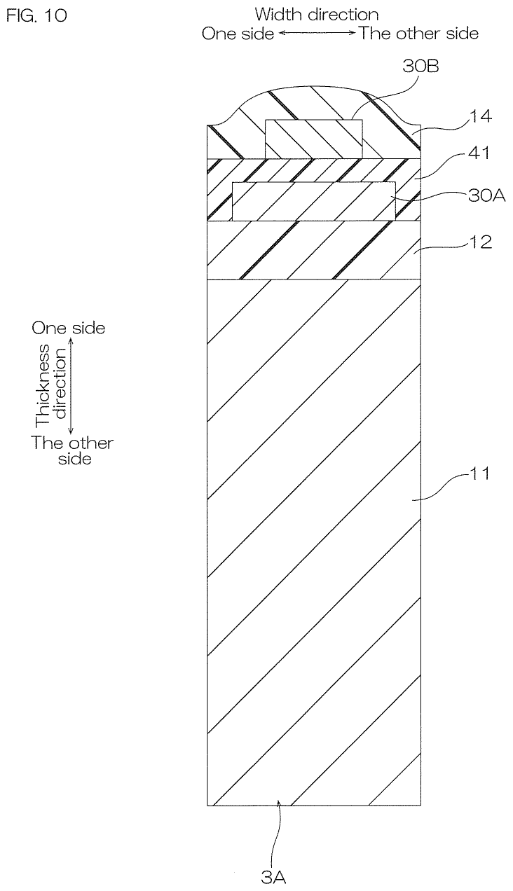

For example, as shown in FIG. 9, the conductive pattern 30 may have a first conductor layer 30A and a second conductor layer 30B. In other words, each of the terminals 301A and 302A and the wire 303A has a first conductor layer 30A and a second conductor layer 30B. The first conductive layer 30A is disposed on the first insulating layer 12. The second conductor layer 30B is disposed on the first conductor layer 30A.
(5) As shown in FIG. 10, the wiring portion 3A may have an intermediate insulating layer 41 between the first conductor layer 30A and the second conductor layer 30B. The intermediate insulating layer 41 is disposed on the first insulating layer 12. The intermediate insulating layer 41 covers the first conductive layer 30A. The second insulating layer 14 is disposed on the intermediate insulating layer 41. The second insulating layer 14 covers the second conductive layer 30B. The second conductor layer 30B is, for example, a signal wire, and the first conductor layer 30A is, for example, a shield-conductor layer.

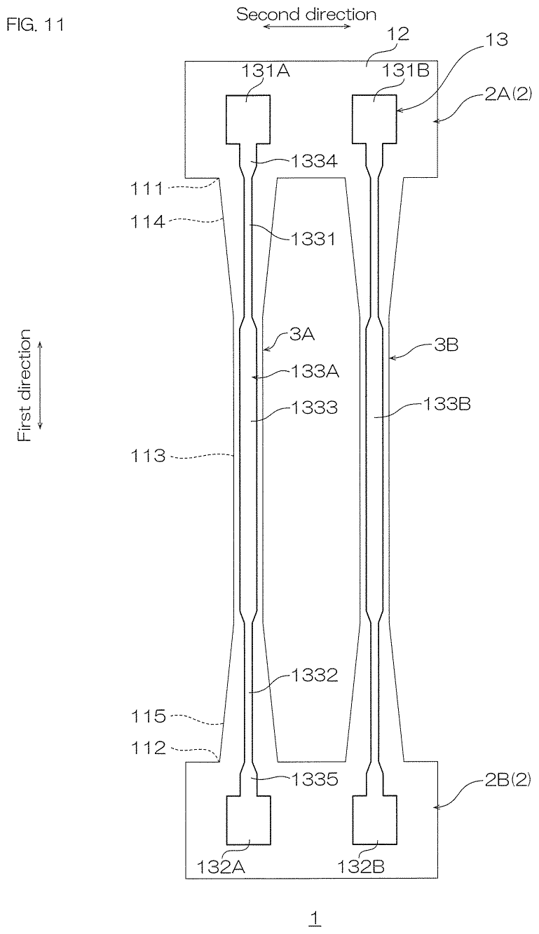

Also in this modified example, as in the above-described embodiment, the metal supporting layer 11 of the wiring portion 3A has a first end portion 111, a second end portion 112, a body portion 113, a first tapered portion 114, and a second tapered portion 115.
(6) As shown in FIG. 11, the wire 133A may have a first portion 1331, a second portion 1332, a third portion 1333, a fourth portion 1334, and a fifth portion 1335.

The first portion 1331, the second portion 1332, and the third portion 1333 are disposed in the wiring portion 3A. The first portion 1331, the second portion 1332, and the third portion 1333 are disposed between the first support portion 2A and the second support portion 2B in the first direction.

The first section 1331 is disposed in the one end portion of the wiring portion 3A and in the vicinity thereof in the first direction. The first portion 1331 overlaps the first tapered portion 114 of the metal supporting layer 11. The first portion 1331 is disposed between the first support portion 2A and the third portion 1333 in the first direction. The first part 1331 is connected to the first support 2A. Specifically, one end portion of the first section 1331 in the first direction is connected to the fourth section 1334 of the wire 133A. The first portion 1331 is thinner than the third portion 1333.

The second portion 1332 is disposed in the other end portion of the wiring portion 3A and in the vicinity thereof in the first direction. The second portion 1332 overlaps the second tapered portion 115 of the metal supporting layer 11. The second portion 1332 is disposed between the second support portion 2B and the third portion 1333 in the first direction. The second portion 1332 is connected to the second support portion 2B. Specifically, the other end portion of the second portion 1332 in the first direction is connected to the fifth portion 1335 of the wire 133A. The second portion 1332 is thinner than the third portion 1333. The width of the second portion 1332 may be the same as the width of the first portion 1331.

The third portion 1333 is disposed between the first portion 1331 and the second portion 1332 in the first direction. The third portion 1333 overlaps the body portion 113 of the metal supporting layer 11. One end portion of the third portion 1333 in the first direction is connected to the first portion 1331. The other end portion of the third portion 1333 in the first direction is connected to the second portion 1332.

The fourth portion 1334 is disposed in the first support portion 2A. One end portion of the fourth section 1334 in the first direction is connected to the terminal 131A. The other end portion of the fourth portion 1334 in the first direction is connected to the first portion 1331. The width of the fourth portion 1334 may be the same as the width of the third portion 1333.

The fifth portion 1335 is disposed in the second support portion 2B. One end portion of the fifth portion 1335 in the first direction is connected to the second portion 1332. The other end portion of the fifth portion 1335 in the first direction is connected to the terminal 132A. The width of the fifth portion 1335 may be the same as the width of the third portion 1333.

In this modified example, in the vicinity of the one end portion of the wiring portion 3A, the metal-supporting layer 11 has a first tapered portion 114, and the wire 133A has a first portion 1331.

Further, in the vicinity of the other end portion of the wiring portion 3A, the metal supporting layer 11 has a second tapered portion 115, and the wire 133A has a second portion 1332.

The first portion 1331 and the second portion 1332 are thinner than the third portion 1333.

Therefore, when the wiring portion 3A is moved, it is possible to further suppress the stress in the vicinity of the end portions of the wiring portion 3A being concentrated in the first portion 1331 and second portion 1332.

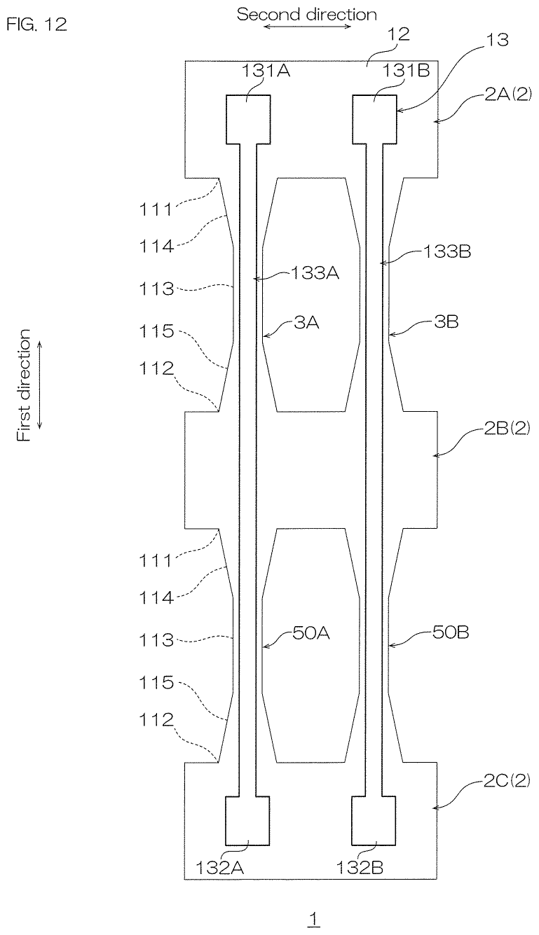

Consequently, it is possible to further suppress the occurrence of a crack in the wire 133A in the vicinity of the end portions of the wiring portion 3A.
(7) The wiring circuit board 1 may have 3 or more support portions 2. For example, as shown in FIG. 12, the wiring circuit board 1 may have a third support portion 2C and a plurality of wiring portions 50A and 50B in addition to the above-described first support portion 2A, second support portion 2B, and plurality of wiring portions 3A and 3B.

In this case, the terminals 132A and 132B are not disposed in the second support portion 2B but disposed in the third support portion 2C. Each of the wires 133A and 133B extends from the first support portion 2A through the second support portion 2B to the third support portion 2C. The middle portion of each of the wires 133A and 133B is disposed in the second support portion 2B.

The third support portion 2C is disposed at an opposite side to the first support portion 2A with respect to the second support portion 2B in the first direction. In other words, the second support portion 2B is disposed between the first support portion 2A and the third support portion 2C in the first direction. The third support portion 2C extends in the second direction. The third support portion 2C supports the other end portion of each of the wiring portions 50A and 50B in the first direction. One end portion of each of the wiring portions 50A and 50B in the first direction is supported by the second support portion 2B.

The wiring portion 50A has the same structure as that of the wiring portion 3A. Specifically, in the same manner as the metal supporting layer 11 of the wiring portion 3A does, the metal supporting layer 11 of the wiring portion 50A has a first end portion 111, a second end portion 112, a body portion 113, a first tapered portion 114, and a second tapered portion 115.

The first end portion 111 of the wiring portion 50A is disposed at the one end portion of the wiring portion 50A in the first direction. The first end portion 111 of the wiring portion 50A is connected to the second support portion 2B in the first direction. The first end portion 111 of the wiring portion 50A is disposed between the second support portion 2B and the first tapered portion 114 in the first direction.

The second end portion 112 of the wiring portion 50A is disposed in the other end portion of the wiring portion 50A in the first direction. The second end portion 112 of the wiring portion 50A is connected to the third support portion 2C in the first direction. The second end portion 112 of the wiring portion 50A is disposed between the third support portion 2C and the second tapered portion 115 in the first direction.

In this modified example, the middle portions of the wires 133A and 133B can be supported by the second support portion 2B.
(8) In the embodiment described above, in the thickness direction, the wiring circuit board 1 includes a conductive pattern 13 at one side of the metal supporting layer 11, and does not include a conductive pattern 13 at the other side of the metal supporting layer 11. In this regard, in the thickness direction, the wiring circuit board 1 may include a conductive pattern 13 at the other side of the metal supporting layer 11. That is, the wiring circuit board 1 may include a first conductive pattern disposed at one side of the metal supporting layer 11 in the thickness direction, and a second conductive pattern disposed on the other side of the metal supporting layer 11 in the thickness direction.
(9) Also in the modified examples (1) to (8), the same operations and effects as those of the above-described embodiment can be obtained.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### Description of Reference Numerals

1 Wiring circuit board
2A First support portion
2B Second support portion
3A Wiring portion
3B Wiring portion
11 Metal supporting layer
12 First insulating layer (an example of an insulating layer)
133A Wire
133B Wire
111 First end portion
112 Second end portion
113 Body portion
114 First tapered portion
115 Second tapered portion

1. A wiring circuit board comprising:
a plurality of wiring portions extending in a first direction and spaced from each other at an interval; and
a first support portion supporting one end portion of each of the plurality of wiring portions in the first direction,
wherein each of the plurality of the wiring portions includes:
a metal supporting layer;
an insulating layer disposed on the metal supporting layer; and
a wire disposed on the insulating layer and extending in the first direction,
wherein the metal supporting layer of the wiring portion includes:
a first end portion connected to the first support portion;
a body portion disposed away from the first end portion; and
a first tapered portion disposed between the first end portion and the body portion, and
wherein a width of the first tapered portion increases as the first tapered portion goes from the body portion toward the first end portion.

2. The wiring circuit board according to claim 1,
wherein in the first direction, a length of the first tapered portion is 30% or less of a total length of the wiring portion.

3. The wiring circuit board according to claim 1,
wherein the first end portion in the first direction has a length of 200 μm or less.

4. The wiring circuit board according to claim 1,
wherein the first tapered portion has a taper ratio of 0.0010 or more.

5. The wiring circuit board according to claim 1,
wherein an edge of the first tapered portion in a width direction includes a curve.

6. The wiring circuit board according to claim 1,
wherein an edge of the first tapered portion in a width direction is a straight line.

7. The wiring circuit board according to claim 1, further comprising:
a second support portion supporting the other end portion of each of the plurality of the wiring portions in the first direction,
wherein the metal supporting layer of the wiring portion further includes:
a second end portion disposed away from the body portion and connected to the second support portion; and
a second tapered portion disposed between the second end portion and the body portion, and
wherein a width of the second tapered portion increases as the second tapered portion goes from the body portion toward the second end portion.

8. The wiring circuit board according to claim 7,
wherein in the first direction, a length of the second tapered portion is 30% or less of a total length of the wiring portion.

9. The wiring circuit board according to claim 7,
wherein the second end portion in the first direction has a length of 200 μm or less.

10. The wiring circuit board according to claim 7,
wherein the second tapered portion has a taper ratio of 0.0010 or more.

11. The wiring circuit board according to claim 7,
wherein an edge of the second tapered portion in the width direction includes a curve.

12. The wiring circuit board according to claim 7,
wherein an edge of the second tapered portion in the width direction is a straight line.

13. The wiring circuit board according to claim 1,
wherein each of the plurality of wiring portions has a plurality of wires.
